(19) United States
(12) Patent Application Publication
(10) Pub. No.: US 2024/0155908 A1
(43) Pub. Date: May 9, 2024

(54) DISPLAY PANEL, PREPARING METHOD THEREOF, AND DISPLAY DEVICE

(71) Applicant: Shanghai Tianma Microelectronics Co., Ltd., Shanghai (CN)

(72) Inventor: Zhiwei Zhang, Shanghai (CN)

(73) Assignee: Shanghai Tianma Microelectronics Co., Ltd., Shanghai (CN)

(21) Appl. No.: 18/411,203

(22) Filed: Jan. 12, 2024

(30) Foreign Application Priority Data
Jun. 30, 2023 (CN) 202310801535.8

(51) Int. Cl. H10K 59/38; H10K 59/80; H10K 71/20

(52) U.S. Cl. CPC H10K 59/38; H10K 59/877; H10K 59/879; H10K 59/8792; H10K 71/233; H10K 71/236

(57) ABSTRACT

Provided are a display panel, a preparing method thereof, and a display device. The display panel includes a base substrate, light-emitting units disposed on a side of the substrate and disposed in the display region, a color filter layer disposed on a side of the light-emitting units facing away from the substrate and including multiple color filter units, and an optical adjustment layer disposed on a side of the base substrate and including multiple optical adjustment units. In the thickness direction of the display panel, a color filter unit at least partially overlaps a light-emitting unit. In a first direction, at least one of the optical adjustment units is disposed between adjacent color filter units. The refractive index of the color filter unit is greater than the refractive index of the optical adjustment unit.

### CROSS-REFERENCE TO RELATED APPLICATION(S)

This application claims priority to Chinese Patent Application No. 202310801535.8 filed Jun. 30, 2023, the disclosure of which is incorporated herein by reference in its entirety.

### TECHNICAL FIELD

The present invention relates to the field of display technology, and particularly, relates to a display panel, a preparing method thereof, and a display device.

### BACKGROUND

With the rapid development of display panel technologies, organic light-emitting display panels have become a research hotspot for their advantages such as fast response speed, high brightness, wide viewing angle, and low power consumption. Generally, an organic light-emitting display panel is provided with a color filter layer, and the color filter layer is correspondingly provided with color filters of different colors to achieve the color display of the organic light-emitting display panel. Meanwhile, an optical adjustment layer is also provided in the organic light-emitting display panel to adjust the angle of the emitted light to improve the light extraction efficiency of the organic light-emitting display panel. The color filter layer and the optical adjustment layer are generally prepared using different preparation techniques, which are complex and can easily lead to serious losses in yield and productivity.

### SUMMARY

The present invention provides a display panel, a preparing method thereof, and a display device, which effectively increases the light extraction efficiency, reduces the difficulty of preparation, and improves the preparation yield. Moreover, the number of films is reduced, facilitating the lightening, and thinning of the display panel.

According to an aspect of the present invention, a display panel is provided, and the display panel includes a display region.

The display panel also includes a base substrate, multiple light-emitting units, a color filter layer, and an optical adjustment layer. The multiple light-emitting units are disposed on a side of the base substrate and disposed in the display region. The color filter layer is disposed on a side of the multiple light-emitting units facing away from the base substrate. The color filter layer includes multiple color filter units. In a thickness direction of the display panel, a color filter unit at least partially overlaps a light-emitting unit. The optical adjustment layer is disposed on a side of the base substrate and includes multiple optical adjustment units. In a first direction, at least one of the optical adjustment units is disposed between adjacent color filter units. The first direction is a direction parallel to a flat surface in which the base substrate is disposed. The refractive index of the color filter unit is greater than the refractive index of the optical adjustment unit.

According to another aspect of the present invention, a preparing method for the display panel is provided. The method includes providing a base substrate; preparing multiple light-emitting units on a side of the base substrate; preparing a patterned optical adjustment unit on a side of a light-emitting unit facing away from the base substrate; in a first direction, preparing a color filter unit on at least one side of the optical adjustment unit. In the thickness direction of the display panel, the color filter unit at least partially overlaps the light-emitting unit; the first direction is a direction parallel to a flat surface in which the base substrate is disposed; the refractive index of the color filter unit is greater than the refractive index of the optical adjustment unit.

According to another aspect of the present invention, a display device is provided and includes a display panel which includes a display region, and includes a base substrate, multiple light-emitting units, a color filter layer, and an optical adjustment layer. The multiple light-emitting units are disposed on a side of the base substrate and disposed in the display region. The color filter layer is disposed on a side of the multiple light-emitting units facing away from the base substrate. The color filter layer includes multiple color filter units. In a thickness direction of the display panel, a color filter unit at least partially overlaps a light-emitting unit. The optical adjustment layer is disposed on a side of the base substrate and includes multiple optical adjustment units. In a first direction, at least one of the optical adjustment units is disposed between adjacent color filter units. The first direction is a direction parallel to a flat surface in which the base substrate is disposed. The refractive index of the color filter unit is greater than the refractive index of the optical adjustment unit.

It is to be understood that the contents described in this part are not intended to identify key or important features of embodiments of the present invention and are not intended to limit the scope of the present invention. Other features of the present invention are apparent from the description provided hereinafter.

### BRIEF DESCRIPTION OF DRAWINGS

To illustrate technical solutions in embodiments of the present invention more clearly, accompanying drawings used in the description of the embodiments are briefly described below. Apparently, the accompanying drawings described below illustrate part of embodiments of the present invention, and those of ordinary skill in the art may acquire other accompanying drawings based on the accompanying drawings described below on the premise that no creative work is done.

FIG. 1 shows a schematic diagram illustrating a structure of a display panel according to an embodiment of the present invention.

FIG. 2 shows a schematic diagram illustrating a sectional structure taken along the section line AA′ of the display panel shown in FIG. 1.

FIG. 3 shows a schematic diagram illustrating another sectional structure taken along the section line AA′ of the display panel shown in FIG. 1.

FIG. 4 shows a schematic diagram illustrating another sectional structure taken along the section line AA′ of the display panel shown in FIG. 1.

FIG. 5 shows a schematic diagram illustrating a structure of a display panel in the related art.

FIG. 6 shows a schematic diagram illustrating another sectional structure taken along the section line AA′ of the display panel shown in FIG. 1.

FIG. 7 shows a schematic diagram illustrating another sectional structure taken along the section line AA′ of the display panel shown in FIG. 1.

FIG. 8 shows a schematic diagram illustrating a structure of a color filter unit according to an embodiment of the present invention.

FIG. 9 shows a schematic diagram illustrating another sectional structure taken along the section line AA′ of the display panel shown in FIG. 1.

FIG. 10 shows a schematic diagram illustrating another structure of a color filter unit according to an embodiment of the present invention.

FIG. 11 shows a schematic diagram illustrating another sectional structure taken along the section line AA′ of the display panel shown in FIG. 1.

FIG. 12 shows a schematic diagram illustrating another sectional structure taken along the section line AA′ of the display panel shown in FIG. 1.

FIG. 13 shows a schematic diagram illustrating another sectional structure taken along the section line AA′ of the display panel shown in FIG. 1.

FIG. 14 shows a schematic diagram illustrating another sectional structure taken along the section line AA′ of the display panel shown in FIG. 1.

FIG. 15 shows a schematic diagram illustrating another sectional structure taken along the section line AA′ of the display panel shown in FIG. 1.

FIG. 16 shows a schematic diagram illustrating another sectional structure taken along the section line AA′ of the display panel shown in FIG. 1.

FIG. 17 shows a schematic diagram illustrating another sectional structure taken along the section line AA′ of the display panel shown in FIG. 1.

FIG. 18 shows a schematic diagram illustrating another sectional structure taken along the section line AA′ of the display panel shown in FIG. 1.

FIG. 19 shows a schematic diagram illustrating another sectional structure taken along the section line BB′ of FIG. 1.

FIG. 20 shows a flowchart of a preparing method for a display panel according to an embodiment of the present invention.

FIG. 21 shows another flowchart of a preparing method for a display panel according to an embodiment of the present invention.

FIG. 22 shows another flowchart of a preparing method for a display panel according to an embodiment of the present invention.

FIG. 23 shows another flowchart of a preparing method for a display panel according to an embodiment of the present invention.

FIG. 24 shows another flowchart of a preparing method for a display panel according to an embodiment of the present invention.

FIG. 25 shows a diagram illustrating a structure of a display device according to an embodiment of the present invention.

FIG. 26 shows another diagram illustrating a structure of a display device according to an embodiment of the present invention.

### DETAILED DESCRIPTION

The solutions in embodiments of the present invention are described clearly and completely in conjunction with drawings in the embodiments of the present invention from which the solutions are better understood by those skilled in the art. Apparently, the embodiments described below are part, not all, of the embodiments of the present invention. Based on the embodiments described herein, all other embodiments acquired by those skilled in the art on the premise that no creative work is done are within the scope of the present invention.

It is to be noted that terms such as “first” and “second” in the description, claims, and drawings of the present invention are used to distinguish between similar objects and are not necessarily used to describe a particular order or sequence. It should be understood that the data used in this manner are interchangeable where appropriate so that the embodiments of the present invention described herein may also be implemented in a sequence not illustrated or described herein. Additionally, terms “comprising”, “including”, and any other variations thereof are intended to encompass a non-exclusive inclusion. For example, a process, method, system, product, or device that includes a series of steps or units not only includes the expressly listed steps or units but may also include other steps or units that are not expressly listed or are inherent to such a process, method, product, or device.

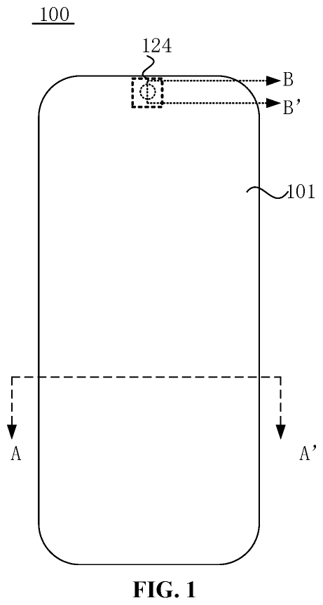

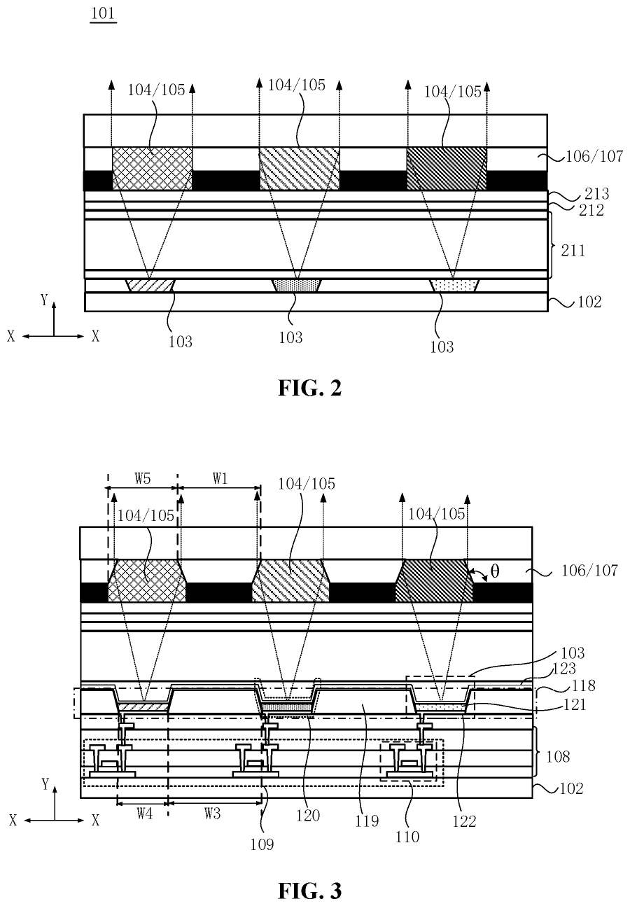

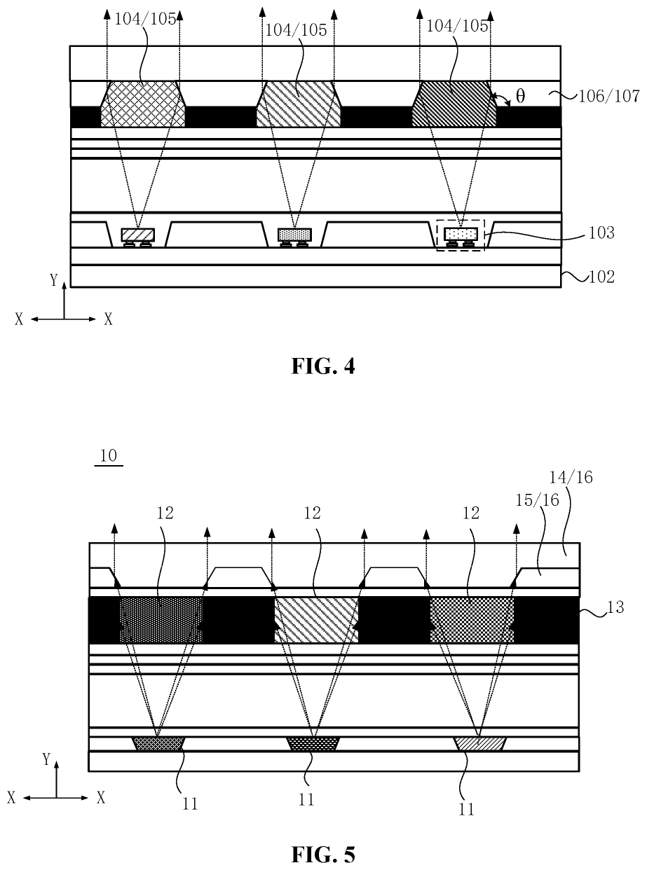

FIG. 1 shows a schematic diagram illustrating a structure of a display panel according to an embodiment of the present invention. FIG. 2 shows a schematic diagram illustrating a sectional structure taken along the section line AA′ of the display panel shown in FIG. 1. FIG. 3 shows a schematic diagram illustrating another sectional structure taken along the section line AA′ of the display panel shown in FIG. 1. FIG. 4 shows a schematic diagram illustrating another sectional structure taken along the section line AA′ of the display panel shown in FIG. 1. As shown in FIGS. 1, 2, 3, and 4, a display panel 100 includes a display region 101. The display panel 100 also includes a base substrate 102, multiple light-emitting units 103, a color filter layer 104, and an optical adjustment layer 106. The multiple light-emitting units 103 are disposed on a side of the base substrate 102 and disposed in the display region 101. The color filter layer 104 is disposed on a side of the light-emitting units 103 facing away from the base substrate 102. The color filter layer 104 includes multiple color filter units 105. In the thickness direction Y of the display panel 100, a color filter unit 105 at least partially overlaps a light-emitting unit 103. The optical adjustment layer 106 is disposed on a side of the base substrate 102 and includes multiple optical adjustment units 107. In a first direction X, at least one of the optical adjustment units 107 is disposed between adjacent color filter units 105. The first direction X is a direction parallel to a flat surface in which the base substrate 102 is disposed. The refractive index of the color filter unit 105 is greater than the refractive index of the optical adjustment unit 107.

The base substrate 102 may be a rigid base substrate such as a glass base substrate or may be a flexible base substrate such as a polyimide base substrate. The material of the base substrate 102 may be selected according to practical design requirements and is not specifically limited in this embodiment of the present invention. The base substrate 102 is generally provided as a whole, with part disposed in the display region 101 and part disposed in an optical device region 124 to ensure the stability of the overall structure of the display panel 100. The optical device region 124 may be disposed in the display region 101 and has both imaging and display effects, which is conducive to achieving a full-screen display effect. Alternatively, the optical device region 124 may be provided separately and has only the imaging effect. The specific configuration method may be selected according to practical design requirements and is not specifically limited in this embodiment of the present invention. In the present application, an example is taken for illustration where the optical device region 124 has both imaging and display effects. Multiple light-emitting units 103 are disposed on a side of the base substrate 102. The light-emitting units 103 disposed in the display region 101 are used for achieving the display effect of the display panel 100. An encapsulation layer 211 is disposed on a side of the light-emitting unit 103 facing away from the base substrate 102. The encapsulation layer 211 is generally made of a three-layer structure consisting of an inorganic layer, an organic layer, and an inorganic layer. A buffer layer 212 is disposed on a side of the encapsulation layer 211 facing away from the base substrate 102, which plays a certain buffering and planarizing role. A touch layer 213 is disposed on the side of the buffer layer 212 facing away from the base substrate 102 to achieve the touch function of the display panel 100. Illustratively, as shown in FIG. 3, the light-emitting unit 103 may be an organic light-emitting element, that is, an anode, an organic light-emitting layer, and a cathode are sequentially disposed in the thickness direction Y of the display panel 100. For the display panel 100 to achieve color display, the light-emitting unit 103 includes at least a red light-emitting unit, corresponding to which a red organic light-emitting layer is provided; a green light-emitting unit, corresponding to which a green organic light-emitting layer is provided; a blue light-emitting unit, corresponding to which a blue organic light-emitting layer is provided. As shown in FIG. 4, the light-emitting unit 103 may also be a micro-light-emitting element such as a sub-millimeter light-emitting diode (Mini LED) or a micron light-emitting diode (Micro LED). As shown in FIG. 3, a drive circuit layer 108 is disposed between the light-emitting unit 103 and the base substrate 102, the drive circuit layer 108 is provided with multiple pixel drive circuits 109 and is electrically connected to the light-emitting unit 103 through the pixel driving circuit 109. The pixel drive circuit 109 is used for supplying a drive signal to the light-emitting unit 103 to ensure normal display. Depending on the drive method of the light-emitting unit 103, the specific configuration manner of the pixel drive circuit 109 may be different. In an embodiment, when the drive method of the light-emitting unit 103 is an active drive, the pixel drive circuit 109 may include multiple transistors 110 to drive the light-emitting unit 103 to emit light by the transistors 110. That is, the pixel drive circuit 109 may be a 2T1C circuit, namely, a circuit having two transistors and one storage capacitor or may be a 7T1C circuit, namely, a circuit having seven transistors and one storage capacitor. The specific structure of the pixel drive circuit 109 is not limited in this embodiment of the present invention. When the drive method of the light-emitting unit 103 is a passive drive, the pixel drive circuit 109 may include a cathode signal line and an anode signal line, and the cathode signal and the anode signal required to emit light are supplied to the light-emitting unit 103 through the cathode signal line and the anode signal line to drive the light-emitting unit 103 to emit light. The specific configuration manner of the pixel drive circuit 109 is not described in this embodiment of the present invention. The display panel 100 also includes a color filter layer 104 disposed on a side of the light-emitting unit 103 facing away from the base substrate 102. The color filter layer 104 includes multiple color filter units 105. Corresponding to the different colors of the light-emitting units 103, the colors of the color filter units 105 are also different. In the thickness direction Y of the display panel 100, the color filter unit 105 at least partially overlaps the light-emitting unit 103. The color of the light emitted from the overlapping light-emitting unit 103 is the same as that of the color filter unit 105. The color filter unit 105 can perform color filter processing on the light emitted from the light-emitting unit 103 to improve the purity of the emitted light and ensure the display effect. Comparison is made with the related art. FIG. 5 shows a schematic diagram illustrating a structure of a display panel in the related art. As shown in FIG. 5, a light-emitting unit 11 emits light, and a light-shielding unit 13 in the middle of adjacent color filter units 12 absorbs part of the large-angle light emitted from the color filter unit 11 to avoid optical crosstalk between adjacent color filter units 12. However, in the aforementioned method, part of the light is absorbed by the light-shielding unit 13, causing the loss of the emitted light and making it difficult to ensure the light extraction efficiency of the display panel 10. Moreover, in the related art, an optical adjustment unit 16, which is matched with a high refractive index layer 14 and a low refractive index layer 15, is usually disposed on a side of the color filter unit 12 facing away from the substrate to adjust the large-angle light emitted from the color filter unit 12. However, the configuration of the optical adjustment unit 16 increases the difficulty of preparation and the overall thickness of the display panel 10, which is not conducive to the production of the light and thin display panel 10. In the present application, the display panel 100 also includes an optical adjustment layer 106 disposed on a side of the base substrate 102, and the optical adjustment layer 106 includes multiple optical adjustment units 107; in a first direction X that is a direction parallel to a flat surface in which the base substrate 102 is disposed, at least one of the optical adjustment units 107 is disposed between adjacent color filter units 105, and at the edge of the display panel 100, part of color filter units 105 are provided with an optical adjustment unit 107 on only one side; meanwhile, the refractive index of a color filter unit 105 is controlled to be greater than the refractive index of an optical adjustment unit 107, the color filter unit 105 is also served as a high refractive index layer, and the optical adjustment unit 107 is also served as a low refractive index layer. In this manner, the light path of the large-angle light emitted through the sidewall of the color filter unit 105 is adjusted by the optical adjustment unit 107, and meanwhile, the sidewall angle of the color filter unit 105 is adjusted reasonably so that the light can be emitted along the front viewing angle as much as possible, the light extraction efficiency is efficiency improved in the direction of the font viewing angle of the display panel 100, and the difficulty of preparation is reduced.

In this embodiment of the present invention, an optical adjustment layer is disposed on a side of the base substrate and includes multiple optical adjustment units; in a first direction, at least one of the optical adjustment units is disposed between adjacent color filter units, and meanwhile, the refractive index of an color filter unit is controlled to be greater than the refractive index of an optical adjustment unit so that the color filter unit and the optical adjustment unit cooperate to adjust the optical path of the large-angle light emitted from the color filter unit. Thus, the light extraction efficiency at the front viewing angle is improved, and the display effect of the display panel is ensured. Additionally, additional films of the optical adjustment unit are avoided, and films are saved, which facilitates the production of thin and light display panels.

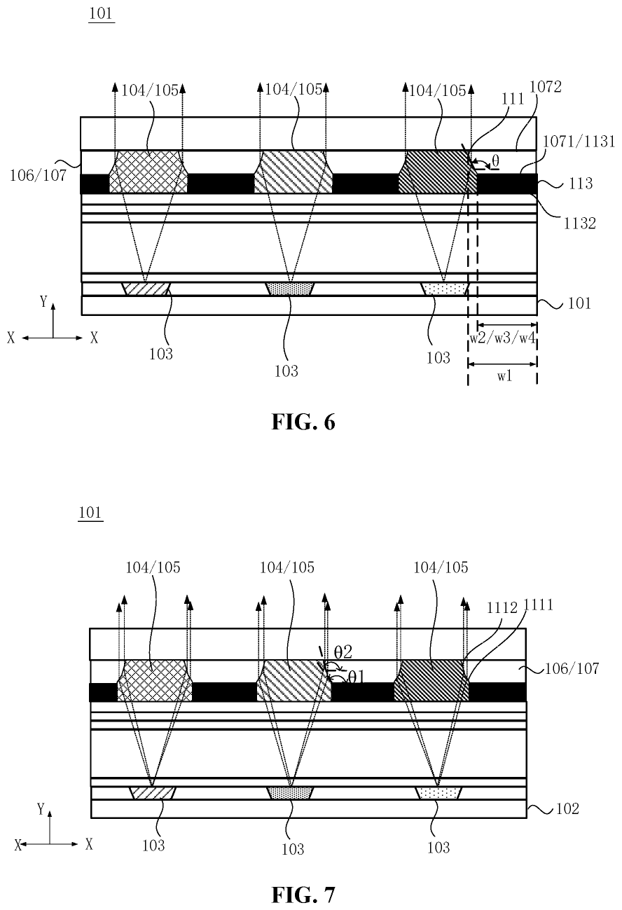

In an embodiment, FIG. 6 shows a schematic diagram illustrating another sectional structure taken along the section line AA′ of the display panel shown in FIG. 1. As shown in FIGS. 3 and 6, the color filter unit 105 includes at least a first sidewall 111 at least partially in contact with an optical adjustment unit 107; and an angle between a tangent to at least one point on the first sidewall 111 and the base substrate 102 and towards a central region of the optical adjustment unit 107 is θ, where 100°≤θ≤160°.

Part of the first sidewall 111 in the color filter unit 105 is in contact with the optical adjustment unit 107, and the large-angle light is emitted to the first sidewall 111 through the color filter unit 105. Due to the difference in refractive index between the color filter unit 105 and the light adjustment unit, the inclination angle of the first sidewall 111 is configured appropriately. In an embodiment, the first sidewall 111 includes a flat surface or a curved surface. The shape of the first sidewall 111 may be selected according to practical design requirements and is not specifically limited in this embodiment of the present invention. Illustratively, as shown in FIG. 3, the first sidewall 111 is a flat surface, and an angle between the first sidewall 111 and the base substrate 102 and towards a central region of the optical adjustment unit 107 is θ. Thus, the light path of the large-angle light can be adjusted at the first sidewall 111 where the color filter unit 105 is in contact with the optical adjustment unit 107 so that the adjusted light is emitted in the direction of the front viewing angle, and the light extraction efficiency is improved. Illustratively, as shown in FIG. 6, the first sidewall 111 is a curved surface, and an angle between a tangent to at least one point on the first sidewall 111 and the base substrate 102 and towards a central region of the optical adjustment unit 107 is θ. Thus, the large-angle light emitted through the color filter unit 105 is gradually adjusted, the adjustment effect of the large-angle light is further improved, and the light extraction efficiency of the display panel 100 is ensured.

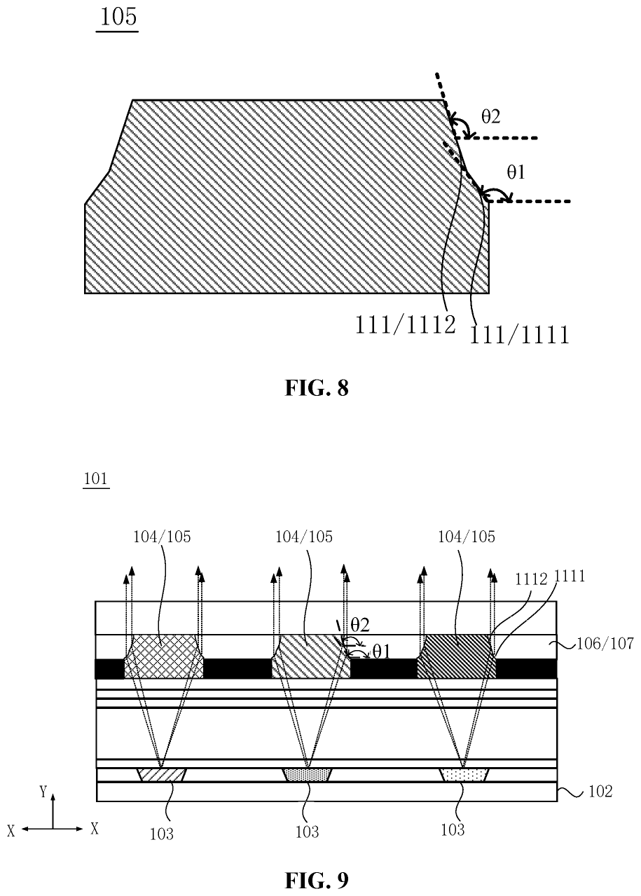

In an embodiment, FIG. 7 shows a schematic diagram illustrating another sectional structure taken along the section line AA′ of the display panel shown in FIG. 1, and FIG. 8 shows a schematic diagram illustrating a structure of a color filter unit according to an embodiment of the present invention. As shown in FIGS. 7 and 8, the first sidewall 111 includes at least a first sub-sidewall 1111 and a second sub-sidewall 1112, the first sub-sidewall 1111 is disposed between the second sub-sidewall 1112 and the base substrate 102, and in the thickness direction Y of the display panel 100, an angle between a tangent to at least one point of the first sub-sidewall 1111 and the base substrate 102 and towards the central region of the optical adjustment unit 107 is different from an angle between a tangent to at least one point of the second sub-sidewall 1112 and the base substrate 102 and towards the central region of the optical adjustment unit 107.

The first sidewall 111 may be arranged in sections, that is, the first sidewall 111 includes multiple sidewalls with different inclination angles. Illustratively, the first sidewall 111 includes a first sub-sidewall 1111 and a second sub-sidewall 1112, and the first sub-sidewall 1111 is disposed between the second sub-sidewall 1112 and the base substrate 102. Illustratively, as shown in FIG. 7, both the first sub-sidewall 1111 and the second sub-sidewall 1112 are flat surfaces, and the inclination angle of the first sub-sidewall 1111 is different from the inclination angle of the second sub-sidewall 1112, to adjust light at different large angles and ensure that the adjusted light can be emitted in the direction of the front viewing angle. Thus, the light extraction efficiency is further improved. The surface shapes of the first sub-sidewall 1111 and the second sub-sidewall 1112 may be the same or different. The specific type of configuration may be selected according to practical design requirements and is not specifically limited in this embodiment of the present invention.

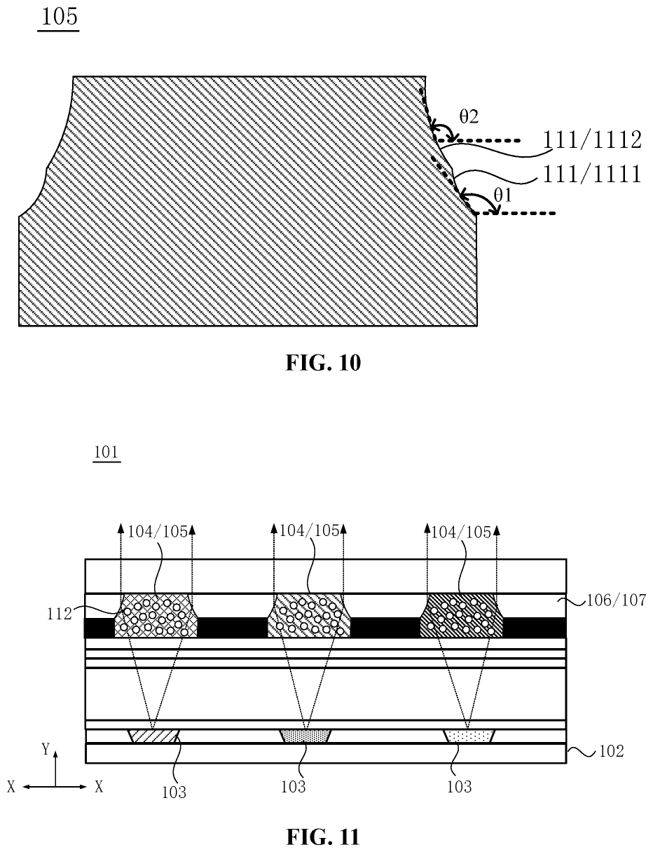

In an embodiment, FIG. 9 shows a schematic diagram illustrating another sectional structure taken along the section line AA′ of the display panel shown in FIG. 1, and FIG. 10 shows a schematic diagram illustrating a structure of another structure of a color filter unit according to an embodiment of the present invention. As shown in FIGS. 9 and 10, in the thickness direction Y of the display panel 100, the angle between the tangent to the at least one point of the first sub-sidewall 1111 and the base substrate 102 and towards the central region of the optical adjustment unit 107 is θ1, and the angle between the tangent to the at least one point of the second sub-sidewall 1112 and the base substrate 102 and towards the central region of the optical adjustment unit 107 is θ2, where θ1>θ2.

Illustratively, the first sub-sidewall 1111 and the second sub-sidewall 1112 may both be curved surfaces, and the angle θ1 between the tangent to at least one point of the first sub-sidewall 1111 and the base substrate 102 and towards the central region of the optical adjustment unit 107 is greater than the angle θ2 between the tangent to at least one point of the second sub-sidewall 1112 and the base substrate 102 and towards the central region of the optical adjustment unit 107. Therefore, the first sub-sidewall 1111 and the second sub-sidewall 1112 adjust the large-angle light at different angles received from the color filter unit 105, the adjustment accuracy of the large-angle light is improved, and it is ensured that the large-angle light adjusted by the first sub-sidewall 1111 and the large-angle light adjusted by the second sub-sidewall 1112 can be emitted in the direction of the front viewing angle. Thus, the light extraction efficiency of the display panel 100 is effectively improved.

In an embodiment, FIG. 11 shows a schematic diagram illustrating another sectional structure taken along the section line AA′ of the display panel shown in FIG. 1. As shown in FIG. 11, at least one color filter unit 105 is provided with scattering particles 112, and the refractive index of the scattering particles 112 is greater than the refractive index of a color filter unit 105.

Scattering particles 112 are disposed in the color filter unit 105. The material of the scattering particle 112 may be titanium dioxide, silicon dioxide, or zirconium dioxide. The refractive index of the scattering particles 112 is greater than the refractive index of the color filter unit 105, and the scattering particle 112 can adjust the light exit direction of the light entering the color filter unit 105. In this manner, the refractive index of the color filter unit 105 is further improved, it is ensured that the emission angle of the large-angle light can be changed between the color filter unit 105 and the optical adjustment unit 107, and the light extraction efficiency of the display panel 100 is further improved.

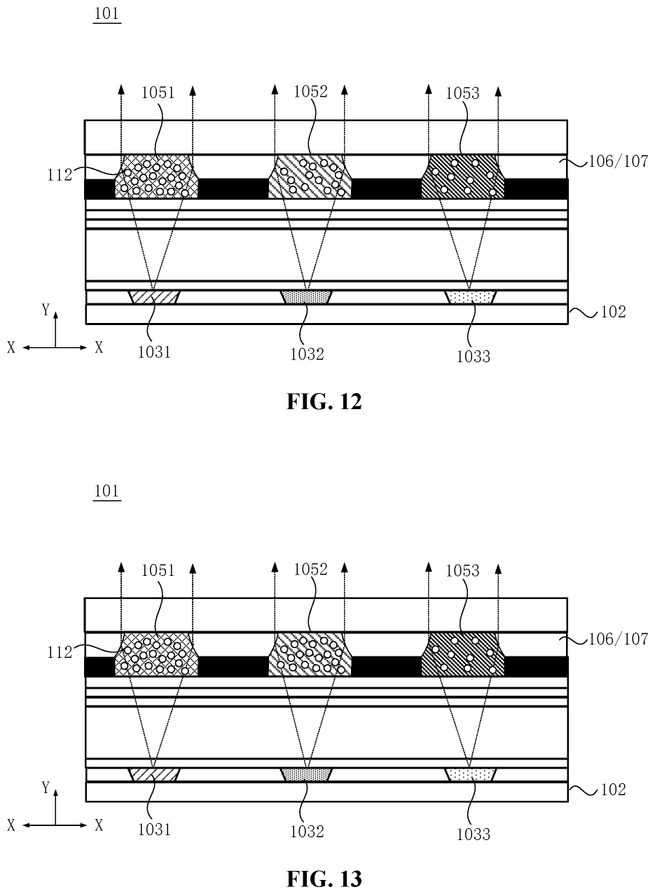

In an embodiment, FIG. 12 shows a schematic diagram illustrating another sectional structure taken along the section line AA′ of the display panel shown in FIG. 1, and FIG. 13 shows a schematic diagram illustrating another sectional structure taken along the section line AA′ of the display panel shown in FIG. 1. As shown in FIGS. 12 and 13, the color filter units 105 include at least a first color filter unit 1051 and a second color filter unit 1052 which have different colors, and the total volume of scattering particles 112 in the first color filter unit 1051 is greater than or equal to the total volume of scattering particles 112 in the second color filter unit 1052.

Corresponding to the light-emitting units 103 of different light-emitting colors, the light-emitting unit 103 includes at least a first light-emitting unit 1031 and a second light-emitting unit 1032, the emission wavelength of the first light-emitting unit 1031 is greater than the emission wavelength of the second light-emitting unit 1032, and the corresponding color filter units 105 includes at least a first color filter unit 1051 and a second color filter unit 1052 which have different colors. Considering the adjustment effect of different color filter units 105 on the light emitted from the light-emitting unit 103, the refractive index of the different color filter units 105 may be differentially configured, and the adjustment may be made by the addition of scattering particles 112 to the color filter unit 105. The material, shape, and size of the scattering particle 112 may be selected according to practical design requirements. In this embodiment of the present invention, the shape of scattering particles 112 is shown as a circle so that the total volume of scattering particles 112 in the first color filter unit 1051 is greater than or equal to the total volume of scattering particles 112 in the second color filter unit 1052. In this manner, the refractive index of different color filter units 105 is different, and the adjustment effect of the optical path of the large-angle light between the color filter unit 105 and the optical adjustment unit 107 is ensured, and the light emission effect in the direction of the front viewing angle is ensured. Moreover, the uniformity of light emission of the display panel 100 is achieved, and the display effect of the display panel 100 is ensured.

In an embodiment, to achieve the color display effect of the display panel 100, the light-emitting unit 103 generally includes a first light-emitting unit 1031, a second light-emitting unit 1032, and a third light-emitting unit 1033 that are different in emitted color. The wavelength of the light emitted by the first light-emitting unit 1031 is greater than the wavelength of the light emitted by the second light-emitting unit 1032, and the wavelength of the light emitted by the second light-emitting unit 1032 is greater than the wavelength of the light emitted by the third light-emitting unit 1033. The corresponding color filter unit 105 includes a first color filter unit 1051 corresponding to the first light-emitting unit 1031, a second color filter unit 1052 corresponding to the second light-emitting unit 1032, and a third color filter unit 1053 corresponding to the third light-emitting unit 1033. To ensure the adjustment effect of the color filter units 105 corresponding to different colors on the emitted light of different colors, the total volume of the scattering particles 112 between the color filter units 105 of different colors is designed to be differentiated to ensure the overall uniformity of light emission of the light emitted after adjustment by the color filter unit 105 and then ensure the display effect of the display panel 100. Since the light absorption capacity of the first color filter unit 1051 is greater than or equal to the light absorption capacity of the second color filter unit 1052, and the light absorption capacity of the second color filter unit 1052 is greater than the light absorption capacity of the third color filter unit 1053, as shown in FIG. 12, the total volume of scattering particles 112 in the first color filter unit 1051 is controlled to be greater than the total volume of scattering particles 112 in the second color filter unit 1052, and the total volume of scattering particles 112 in the second color filter unit 1052 is greater than the total volume of scatterings particle 112 in the third color filter unit 1053. Alternatively, as shown in FIG. 13, the total volume of the scattering particles 112 in the first color filter unit 1051 is controlled to be equal to the total volume of the scattering particles 112 in the second color filter unit 1052, and the total volume of the scattering particles 112 in the second color filter unit 1052 is controlled to be greater than the total volume of the scattering particles 112 in the third color filter unit 1053. The refractive index of each color filter unit 105 is increased so that the light path of large-angle light can be changed between the color filter unit 105 and the optical adjustment unit 107 to improve the light extraction efficiency in the direction of the front viewing angle. Meanwhile, the total volume of the scattering particles 112 between the color filter units 105 of different colors is designed to be differentiated to ensure uniform light emission from the display panel 100 after the light passes through the different color filter units 105 and to ensure the display effect of the display panel 100.

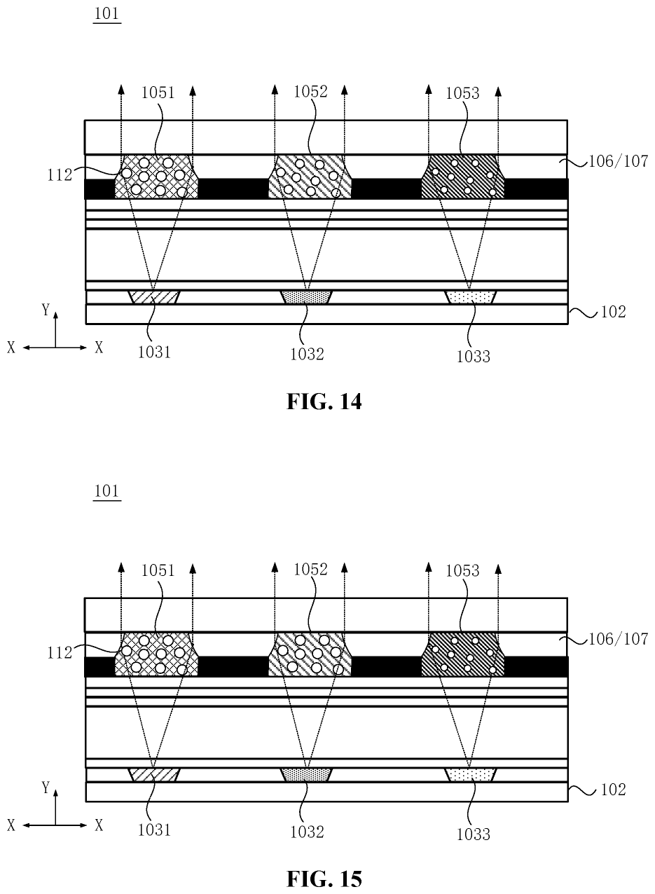

In an embodiment, FIG. 14 shows a schematic diagram illustrating another sectional structure taken along the section line AA′ of the display panel shown in FIG. 1, and FIG. 15 shows a schematic diagram illustrating another sectional structure taken along the section line AA′ of the display panel shown in FIG. 1. As shown in FIGS. 14 and 15, the scattering particles 112 disposed in the first color filter unit 1051 includes a first scattering particle 1121 and the scattering particles 112 disposed in the second color filter unit 1052 includes a second scattering particle 1122, and the particle size of the first scattering particle 1021 is greater than or equal to the particle size of the second scattering particle 1052.

The color filter units 105 include at least a first color filter unit 1051 and a second color filter unit 1052 which have different colors. To ensure the overall display effect of the display panel 100, different color filter units 105 have different adjustment effects on large-angle light. Therefore, it is necessary to carry out a differentiated design in different color filter units 105 so that the total volume of the scattering particles 112 in the first color filter unit 1051 is greater than or equal to the total volume of the scattering particles 112 in the second color filter unit 1052. The number of scattering particles 112 configured in different color filter units 105 is the same, the material is the same, and the particle size of the scattering particles 112 configured in the different color filter units 105 may be adjusted to be different. The first color filter unit 1051 is provided with a first scattering particle 1121, and the second color filter unit 1052 is provided with a second scattering particle 1122 so that the particle size of the first scattering particle 1121 is greater than or equal to the particle size of the second scattering particle 1122, and the difference in light absorption capabilities between different color filter units 105 is balanced to ensure the uniformity of light emission from the display panel 100.

In an embodiment, the color filter unit 105 generally includes a first color filter unit 1051, a second color filter unit 1052, and a third color filter unit 1053. The first color filter unit 1051 is provided a first scattering particle 1121, the second color filter unit 1052 is provided with a second scattering particle 1122, and the third color filter unit 1053 is provided with a third scattering particle 112. Furthermore, to match the adjustment effect of large-angle light at a contact point between the color filter unit 105 and the optical adjustment unit 107, illustratively, the number of scattering particles 112 configured in different color filter units 105 is the same. As shown in FIG. 14, the particle size of the first scattering particle 1121 is greater than the particle size of the second scattering particle 1122, and the particle size of the second scattering particle 1122 is greater than the particle size of the third scattering particle 112 so that the total volume of the scattering particles 112 in the first color filter unit 1051 is greater than the total volume of the scattering particles 112 in the second color filter unit 1052, and the total volume of the scattering particles 112 in the second color filter unit 1052 is greater than the total volume of the scattering particles 112 in the third color filter unit 1053. Alternatively, as shown in FIG. 15, the particle size of the first scattering particle 1121 is equal to the particle size of the second scattering particle 1122, and the particle size of the second scattering particle 1122 is greater than the particle size of the third scattering particle 112 so that the total volume of the scattering particles 112 in the first color filter unit 1051 is equal to the total volume of the scattering particles 112 in the second color filter unit 1052, and the total volume of the scattering particles 112 in the second color filter unit 1052 is greater than the total volume of the scattering particles 112 in the third color filter unit 1053. In this manner, the light extraction efficiency in the direction of the front viewing angle is ensured while the uniformity of the light emitted from the display panel 100 after the light passes through the different color filter units 105. Thus, the display effect of the display panel 100 is ensured.

In an embodiment, with continued reference to FIGS. 12 and 13, the concentration of the scattering particles 112 in the first color filter unit 1051 is greater than or equal to the concentration of the scattering particles 112 in the second color filter unit 1052.

The color filter units 105 include at least a first color filter unit 1051 and a second color filter unit 1052 which have different colors. To ensure the overall display uniformity of the display panel 100, differentiated designs are carried out in different color filter units 105 so that the total volume of the scattering particles 112 in the first color filter unit 1051 is greater than or equal to the total volume of the scattering particles 112 in the second color filter unit 1052. The particle sizes of scattering particles 112 configured in different color filter units 105 are the same, the material is the same, and the concentration of the scattering particles 112 configured in different color filter units 105 may be adjusted to be different. The first color filter unit 1051 is provided with a first scattering particle 1121, and the second color filter unit 1052 is provided with a second scattering particle 1122 so that the concentration of the first scattering particle 1121 is greater than or equal to the concentration of the second scattering particle 1122, and the quantity of the light emitted after the light passes through the first color filter unit 1051 and the second color filter unit 1052 is similar to ensure the uniformity of light emission from the display panel 100.

In an embodiment, the color filter unit 105 generally includes a first color filter unit 1051, a second color filter unit 1052, and a third color filter unit 1053. An example is used where the material and particle size of the scattering particles 112 in different color filter units 105 are the same. As shown in FIG. 12, when the light absorption capacity of the first color filter unit 1051 is greater than the light absorption capacity of the second color filter unit 1052, and the light absorption capacity of the second color filter unit 1052 is greater than the light absorption capacity of the third color filter unit 1053, the concentration of scattering particles 112 in the first color filter unit 1051 is controlled to be greater than the concentration of scattering particles 112 in the second color filter unit 1052, and the concentration of scattering particles 112 in the second color filter unit 1052 is controlled to be greater than the concentration of scattering particles 112 in the third color filter unit 1053 so that the total volume of scattering particles 112 in the first color filter unit 1051 is greater than the total volume of scattering particles 112 in the second color filter unit 1052, and the total volume of scattering particles 112 in the second color filter unit 1052 is greater than the total volume of scattering particles 112 in the third color filter unit 1053. Alternatively, as shown in FIG. 13, when the light absorption capacity of the first color filter unit 1051 is equal to the light absorption capacity of the second color filter unit 1052, and the light absorption capacity of the second color filter unit 1052 is greater than the light absorption capacity of the third color filter unit 1053, the concentration of scattering particles 112 in the first color filter unit 1051 is controlled to be equal to the concentration of scattering particles 112 in the second color filter unit 1052, and the concentration of scattering particles 112 in the second color filter unit 1052 is controlled to be greater than the concentration of scattering particle 112 in the third color filter unit 1053 so that the total volume of scattering particles 112 in the first color filter unit 1051 is equal to the total volume of scattering particles 112 in the second color filter unit 1052, and the total volume of scattering particles 112 in the second color filter unit 1052 is greater than the total volume of scattering particles 112 in the third color filter unit 1053. In the aforementioned method, the refractive index of the color filter unit 105 can be improved, the light extraction efficiency is efficiency enhanced in the direction of the front viewing angle of the display panel 10, and the overall display effect of the display panel 100 is ensured.

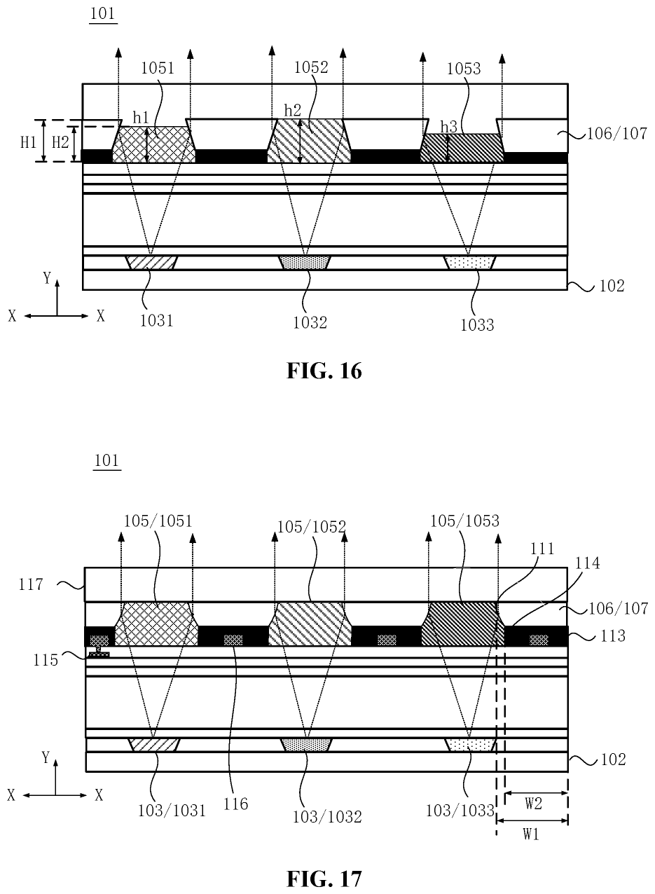

In an embodiment, FIG. 16 shows a schematic diagram illustrating another sectional structure taken along the section line AA′ of the display panel shown in FIG. 1. As shown in FIG. 16, the color filter units 105 include at least a first color filter unit 1051 and a second color filter unit 1052 which have different colors, and in the thickness direction Y of the display panel 100, the thickness h2 of the second color filter unit 1052 is greater than the thickness h1 of the first color filter unit 1051.

The color filter units 105 include at least a first color filter unit 1051 and a second color filter unit 1052 which have different colors. Different color filter units 105 have different light absorption capabilities, which affects the quantity of light emitted through different color filter units. The overall display effect of the display panel 100 can be ensured by performing differentiated designs on different color filter units 105. In an embodiment, the thickness difference between the first color filter unit 1051 and the second color filter unit 1052 may be adjusted. The light absorption capacity of the first color filter unit 1051 is greater than the light absorption capacity of the second color filter unit 1052 so that the thickness h2 of the second color filter unit 1052 is greater than the thickness h1 of the first color filter unit 1051. In this manner, the quantity of light emitted after the light passes through the first color filter unit 1051 and the second color filter unit 1052 is similar, ensuring the uniformity of the light emission of the display panel 100.

In an embodiment, the color filter unit 105 in the display panel 100 generally includes a first color filter unit 1051, a second color filter unit 1052, and a third color filter unit 1053 of different colors. Since the wavelength of the light emitted by the first color filter unit 1051 is greater than the wavelength of the light emitted by the second color filter unit 1052, and the wavelength of the light emitted by the second color filter unit 1052 is greater than the wavelength of the light emitted by the third color filter unit 1053, a large difference is avoided in the quantity of light emitted through different color filter units 105, and the resultant influence on the display uniformity is avoided. Therefore, to balance the light emission effects between different color filter units 105, if the surface of the different color filter units 105 facing away from the base substrate 102 is a flat surface, in the thickness direction Y of the display panel 100, the thickness h2 of the second color filter unit 1052 is adjusted to be greater than the thickness h1 of the first color filter unit 1051, and the thickness h1 of the first color filter unit 1051 is adjusted to be greater than the thickness h3 of the third color filter unit 1053. Thus, the differential design of the thickness between different color filter units 105 is achieved, and it is ensured that the light path is adjusted at the contact point between the light emitted by the color filter units 105 of different colors and the optical adjustment unit 107 to improve the light extraction efficiency in the direction of the front viewing angle. Moreover, the uniformity of the light emitted between different color filter units 105 is ensured, and the display effect of the display panel 100 is ensured.

In an embodiment, FIG. 17 shows a schematic diagram illustrating another sectional structure taken along the section line AA′ of the display panel shown in FIG. 1. As shown in FIG. 17, the display panel also includes a light-shielding unit 113 disposed on at least one side of the color filter unit 105 in the first direction X, and the light-shielding unit 113 is disposed on a side of the optical adjustment unit 107 facing to the base substrate 102; the color filter unit 105 also includes a second sidewall 114 interconnected to the first sidewall 111, the second sidewall 114 is at least partially in contact with the light-shielding unit 113, and the first sidewall 111 is not in contact with the light-shielding unit 113; in the thickness direction Y of the display panel 100, the optical adjustment unit 107 at least partially overlaps the light-shielding unit 113.

The display panel 100 is provided with a light-shielding unit 113 disposed on at least one side of the color filter unit 105 in the first direction X. The light-shielding unit 113 is generally an opaque black light-shielding material, which can avoid optical crosstalk between different color filter units 105. Along the thickness of the display panel 100, the light-shielding unit 113 is disposed on a side of the optical adjustment unit 107 facing to the base substrate 102. In the thickness direction Y of the display panel 100, the optical adjustment unit 107 at least partially overlaps the light-shielding unit 113, and the surface of the light-shielding unit 113 facing away from the base substrate 102 is in contact with the surface of the optical adjustment unit 107 facing to the base substrate 102. The color filter unit 105 also includes a second sidewall 114 interconnected to the first sidewall 111. The second sidewall 114 is partially in contact with the light-shielding unit 113. The included angle between the first sidewall 111 and the base substrate 102 is a right angle. In the thickness direction Y of the display panel 100, the height of the first sidewall 111 is the same as the height of the light-shielding unit 113, and the first sidewall 111 is not in contact with the light-shielding unit 113. Part of the light emitted by the color filter unit 105 through the second sidewall 114 is absorbed by the light-shielding unit 113. The adjustment of a light emission angle occurs at part of the light emitted by the color filter unit 105 through the first sidewall 111, and the light is emitted through the optical adjustment unit 107 while the light emission direction is towards the direction of the front viewing angle to ensure the light extraction efficiency of the display panel 100.

As shown in FIG. 17, a first touch layer 115 may also be disposed between the color filter unit 105 and the light-emitting unit 103, a second touch layer 116 is disposed on a side of the first touch layer 115 facing away from the base substrate 102, and in the thickness direction Y of the display panel 100, the second touch layer 116 overlaps and is covered by the light-shielding unit 113. Thus, additional touch layers are avoided, which helps reduce the thickness of the display panel 100 and facilitates the production of the thin and light display panel 100. The second touch layer 116 is connected to the first touch layer 115 through a via. The first touch layer 115 and the second touch layer 116 form a capacitive touch structure to ensure the touch effect of the display panel 100.

In an embodiment, with continued reference to FIG. 17, in the first direction, the extending width W1 of the optical adjustment unit 107 is greater than or equal to the extending width W2 of the light-shielding unit 113.

Illustratively, as shown in FIG. 17, the surface of the optical adjustment unit 107 facing to the base substrate 102 is in contact with the surface of the light-shielding unit 113 facing away from the base substrate 102. The size of the contact surfaces may be the same. In the thickness direction Y of the display panel 100, the optical adjustment unit 107 at least partially overlaps the light-shielding unit 113, and the optical adjustment unit 107 has a portion that does not overlap the light-shielding unit 113. That is, the orthographic projection of the light-shielding unit 113 on the substrate 102 falls within the orthographic projection of the optical adjustment unit 107 on the substrate 102. That is, in the first direction X, the extending width of the optical adjustment unit 107 is equal to the extending width of the light-shielding unit 113. Meanwhile, since the optical adjustment unit 107 is in contact with the first sidewall 111 of the color filter unit 105, and the first sidewall 111 has an inclination angle facing the central region of the optical adjustment unit 107, the surface size of the optical adjustment unit 107 facing away from the base substrate 102 is greater than the surface size of the optical adjustment unit 107 facing to the base substrate 102. That is, in the first direction X, the extending width of the optical adjustment unit 107 is greater than the extending width of the light-shielding unit 113. Thus, the adjustment effect of the large-angle light is ensured, and the light extraction efficiency of the front viewing angle is improved.

In an embodiment, with continued reference to FIG. 6, the optical adjustment unit 107 includes a first surface 1071 facing to a side of the base substrate 102 and a second surface 1072 facing away from the side of the base substrate 102, the light-shielding unit 113 includes a third surface 1131 facing away from the side of the base substrate 102, the first surface 1071 is in contact with the third surface 1131, and in the first direction X, the extending width w1 of the first surface 1071 is less than the extending width w2 of the second surface 1072, and the extending width w3 of the third surface 1131 is equal to the extending width w4 of the first surface 1071.

Illustratively, the optical adjustment unit 107 includes a first surface 1071 facing to the side of the base substrate 102 and a second surface 1072 facing away from the side of the base substrate 102, and the light-shielding unit 113 includes a third surface 1131 facing away from the side of the substrate and a fourth surface 1132 facing to the side of the substrate. In the first direction X, the third surface 1131 and the fourth surface 1132 have the same extending width, and the first surface 1071 is in contact with the third surface 1131. In the first direction X, the extending width w1 of the first surface 1071 is less than the extending width w2 of the second surface 1072, the extending width w3 of the third surface 1131 is equal to the extending width w4 of the first surface 1071, and the extending width w2 of the second surface 1072 is greater than the extending width w3 of the third surface 1131. In this manner, the sidewall of the optical adjustment unit 107 matches the first sidewall 111 of the color filter unit 105, thereby ensuring the adjustment effect of the optical path of the large-angle light emitted through the color filter unit 105 at the second sidewall 114. Thus, the light extraction efficiency in the direction of the front viewing angle is improved, and the display effect of the display panel 100 is ensured.

In an embodiment, with continued reference to FIG. 16, in the thickness direction Y of the display panel 100, the sum H1 of the height of the light-shielding unit 113 and the height of the optical adjustment unit 107 is greater than the height H2 of the color filter unit 105.

In the thickness direction Y of the display panel 100, the sum H1 of the height of the light-shielding unit 113 and the height of the optical adjustment unit 107 is configured to be greater than the height H2 of the color filter unit 105. That is, since the surface of the color filter unit 105 may be uneven in the preparation process, the maximum height H2 in the color filter units 105 is less than the sum H1 of the height of the light-shielding unit 113 and the height of the optical adjustment unit 107. Thus, it is ensured that the light path of the large-angle light emitted through the color filter unit 105 can be adjusted at the contact point between the first sidewall 111 and the optical adjustment unit 107 as much as possible so that the light is deflected at a certain angle and then emitted in the direction of the front viewing angle, thereby ensuring the light extraction efficiency.

In an embodiment, with continued reference to FIG. 17, the display panel 100 also includes a low refractive index layer 117 disposed on a side of the color filter unit 105 facing away from the base substrate 102; in the thickness direction Y of the display panel 100, the low refractive index layer 117 at least partially overlaps the color filter unit 105 and a light-shielding unit separately, and the refractive index of the low refractive index layer 117 is less than the refractive index of the color filter unit 105.

The display panel 100 is also provided with a low refractive index layer 117 disposed on a side of the color filter unit 105 facing away from the base substrate 102. The low refractive index layer 117 has a refractive index between 1.45 to 1.55. In the thickness direction Y of the display panel 100, the low refractive index layer 117 at least partially overlaps the color filter unit 105 and a light-shielding layer separately, that is, the low refractive index layer 117 is generally provided as a whole. The height of the low refractive index layer 117 is generally between 1.2 to 15.5 μm, which can provide a certain flattening effect. Moreover, the low refractive index layer 117 is a light-transmitting material, which can ensure the light emission effect. The refractive index of the low refractive index layer 117 is less than the refractive index of the color filter unit 105, which allows the front-view light emitted through the color filter unit 105 to emit through the low refractive index layer 117 and then ensures the light emission effect at the front viewing angle.

In an embodiment, with continued reference to FIG. 17, the refractive index of the low refractive index layer 117 is less than or equal to the refractive index of the optical adjustment unit 107.

As shown in FIG. 17, the refractive index of the low refractive index layer 117 is less than or equal to the refractive index of the optical adjustment unit 107 so that the front-view light emitted after adjustment at the contact point between the first sidewall 111 of the color filter unit 105 and the optical adjustment unit 107 can be normally emitted, thereby ensuring the light extraction efficiency at the front viewing angle of the display panel 100.

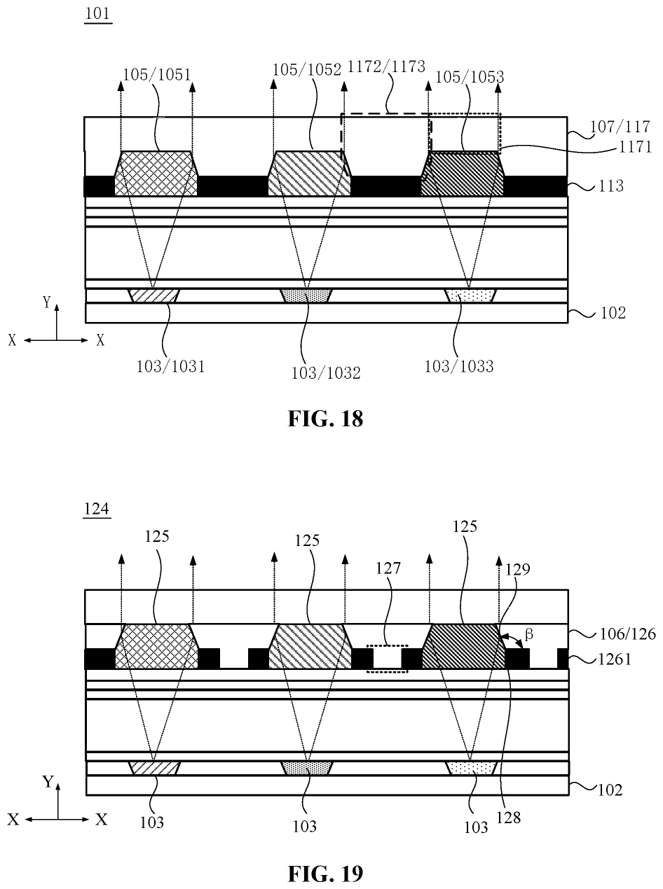

In an embodiment, FIG. 18 shows a schematic diagram illustrating another sectional structure taken along the section line AA′ of the display panel shown in FIG. 1. As shown in FIG. 18, part of the low refractive index layer 117 is also served as the optical adjustment unit 107.

In the thickness direction Y of the display panel 100, part of the low refractive index layer 117 overlapping the light-shielding unit 113 may be also served as the optical adjustment unit 107. The optical adjustment unit 107 is formed synchronously in the preparation process of the low refractive index layer 117. This part of the low refractive index layer 117 is in contact with the first sidewall 111 of the color filter unit 105 and the third surface 1131 of the light-shielding unit 113 separately to adjust the optical path of large-angle light, improve the light emission at the front viewing angle, and avoid additional process steps to configure the optical adjustment unit 107. Thus, the technique cost and the difficulty are reduced.

In an embodiment, as shown in FIG. 18, the low refractive index layer 117 includes a first low refractive index section 1171 and a second low refractive index section 1172 connected to each other; in the thickness direction Y of the display panel 100, the first low refractive index section 1171 at least partially overlaps the color filter unit 105, and the second low refractive index section 1172 at least partially overlaps the light-shielding unit 113; the second low refractive index section 1172 includes a low refractive index sub-section 1173, the low refractive index sub-section 1173 is in contact with the light-shielding unit 113 and the first sidewall 111 of the color filter unit 105, and the low refractive index sub-section 1173 is also served as the optical adjustment unit 107. In this manner, the light path of the large-angle light emitted through the color filter unit 105 is adjusted at the contact point between the low refractive index sub-section 1173 and the color filter unit 105. Thus, the light extraction efficiency in the direction of the front viewing angle is improved, and the display effect of the display panel 100 is ensured.

In an embodiment, as shown in FIG. 3, the display panel 100 includes a pixel definition layer 118 disposed on a side of the base substrate 102, the pixel definition layer 118 is provided with pixel definition structures 119 and first openings 120, each of which is disposed between adjacent pixel definition structures 119, and in the thickness direction Y of the display panel 100, the first opening 120 at least partially overlaps a light-emitting unit 103 and a color filter unit 105 separately, and the pixel definition structure 119 at least partially overlaps an optical adjustment unit 107.

Illustratively, when light-emitting unit 103 is an organic light-emitting element, the display panel 100 is also provided with a pixel definition layer 118. The pixel definition layer 118 is provided with pixel definition structures 119 and a first opening 120. The first opening 120 is disposed between adjacent pixel definition structures 119. The first opening 120 determines the light-emitting area of the light-emitting unit 103. In the thickness direction Y of the display panel 100, the first opening 120 at least partially overlaps the light-emitting unit 103 and the color filter unit 105 separately, and the pixel definition structure 119 at least partially overlaps the optical adjustment unit 107. The light-emitting unit 103 includes a light-emitting layer 121 disposed in the first opening 120. The light-emitting layer 121 is disposed between an anode 122 and a cathode 123. A pixel drive circuit 109 applies voltage to a first electrode 122 and a second electrode 123 to control the light-emitting unit 103 to emit light, thus ensuring the display effect of the display panel 100.

In an embodiment, with continued reference to FIG. 3, in the first direction X, the extending width W3 of the pixel definition structure 119 is greater than the extending width W1 of the optical adjustment unit 107.

In the first direction X, the extending width W3 of the pixel definition structure 119 is controlled to be greater than the extending width W1 of the optical adjustment unit 107, and the extending width W4 of the light-emitting unit 103 is controlled to be less than the extending width W5 of the color filter unit 105, thereby ensuring the color filter effect of the color filter unit 105 on the light emitted from the light-emitting unit 103 and enabling the light path of the large-angle light emitted through the color filter unit 105 to be adjusted at the contact point between the color filter unit 105 and the optical adjustment unit 107. In this manner, the light extraction efficiency at the front viewing angle is improved, and the display effect of the display panel 100 is ensured.

In an embodiment, with continued reference to FIG. 3, the refractive index of the color filter unit 105 is n1, and the refractive index of the optical adjustment unit 107 is n2, where n1≥1.65, and 1.4≤n2≤1.6. The refractive index of the color filter unit 105 and the optical adjustment unit 107 is reasonably selected to ensure the adjustment effect of large-angle light. The refractive index of the color filter unit 105 and the optical adjustment unit 107 may be selected according to practical design requirements and is not specifically limited in this embodiment of the present invention.

In an embodiment, with continued reference to FIG. 3, the optical adjustment unit 107 is made of a light-transmitting material. This allows the emitted light after adjustment at the contact point between the color filter unit 105 and the optical adjustment unit 107 to be emitted through the optical adjustment unit 107, thereby improving the light extraction efficiency.

In an embodiment, FIG. 19 shows a schematic diagram illustrating another sectional structure taken along the section line BB′ of FIG. 1. As shown in FIG. 19, the display panel 100 also includes an optical device region 124, and the optical device region 124 includes multiple color filter sub-units 125 disposed on a side of the base substrate 102; the optical adjustment layer 106 includes multiple optical adjustment sub-units 126; in the first direction X, at least one of the optical adjustment sub-units 107 is disposed between adjacent color filter sub-units 125, and the refractive index of a color filter sub-unit 125 is greater than the refractive index of an optical adjustment sub-unit 126.

The display panel 100 is provided with an optical device region 124 that can achieve both the display effect and the imaging effect. The optical device region 124 may be also served as a configuration region of a sensor. The sensor may be a camera or an infrared sensor and is not limited in this embodiment of the present invention. Therefore, in addition to the normal display function, the optical device region 124 should also have a good light-transmitting effect to ensure that external light can enter the camera through the optical device region 124. To ensure the display effect, the optical device region 124 is provided with a light-emitting unit 103. The arrangement density of the light-emitting units 103 disposed in the optical device region 124 may be configured to be smaller than the arrangement density of the light-emitting elements disposed in the normal display region 101 to ensure light transmittance. The optical device region 124 includes multiple color filter sub-units 125 disposed on a side of the base substrate 102 for performing color filter processing on the light emitted from the light-emitting unit 103 to improve optical purity. The optical adjustment layer 106 includes multiple optical adjustment sub-units 126. In the first direction X, at least part of the optical adjustment sub-unit 107 is disposed between adjacent color filter sub-units 125. The refractive index of the color filter sub-unit 125 is greater than the refractive index of the optical adjustment sub-unit 126. Thus, the light path of the large-angle light emitted from the color filter sub-unit 125 in the optical device region 124 can be adjusted at the contact point between the color filter sub-unit 125 and the optical adjustment sub-unit 126, thereby improving the light extraction efficiency in the direction of the front viewing angle and ensuring the display effect of the optical device region 124.

In an embodiment, as shown in FIG. 19, the optical device region 124 includes a light-shielding sub-unit 1261 and the optical adjustment sub-unit 126; the light-shielding sub-unit 1261 is disposed on a side of the optical adjustment sub-unit 126 facing to the base substrate 102 and between the adjacent color filter sub-units 125, and the light-shielding sub-unit includes a second opening 127; the optical adjustment sub-unit 126, among the at least one optical adjustment sub-unit 126 disposed between the adjacent color filter sub-units 125, at least partially overlaps both the light-shielding sub-unit 1261 and the second opening 127 in the thickness direction Y of the display panel 100.

The light-shielding sub-unit 1261 is disposed between adjacent color filter sub-units 125, which can reduce the risk of optical crosstalk between adjacent color filter sub-units 125. The light-shielding sub-unit 1261 includes a second opening 127. In the thickness direction Y of the display panel 100, the optical adjustment sub-unit 126 disposed between adjacent color filter sub-units 125 at least partially overlaps the light-shielding sub-unit 1261 and the second opening 127, that is, the second opening 127 is filled with the optical adjustment sub-units 126. The optical adjustment sub-unit 126 is a light-transmitting material to ensure the light transmittance of the optical device region 124, and meanwhile, the adjustment effect of the optical path of the large-angle light at the contact point between the optical adjustment sub-unit 126 and the color filter sub-unit 125 is ensured. Thus, the light extraction efficiency in the direction of the front viewing angle is improved.

In an embodiment, as shown in FIG. 19, the optical adjustment sub-unit 126 includes a third sidewall 128 and a fourth sidewall 129 connected to each other, the third sidewall 128 is at least partially in contact with the light-shielding sub-unit 1261, the fourth sidewall 129 is not in contact with the light-shielding sub-unit 1261, and an angle between a tangent to at least one point of the fourth sidewall 128 and the base substrate 126 and towards a central region of the optical adjustment sub-unit is β, where 100°≤β≤160°.

The optical adjustment sub-unit 126 includes a third sidewall 128 and a fourth sidewall 129 connected to each other. The third sidewall 128 is at least partially in contact with the light-shielding unit 1261. The fourth sidewall 129 is not in contact with the light-shielding unit 1261. The inclination angle of the fourth sidewall 129 is reasonably configured. The third sidewall 128 may be a flat surface or a curved surface. An angle between a tangent to at least one point of the fourth sidewall 129 and the base substrate 102 and towards a central region of the optical adjustment sub-unit 126 is β, where 100° ≤β≤160°. Thus, the light path of the large-angle light emitted through the color filter sub-unit 125 is adjusted to ensure the light extraction efficiency of the display panel 100. The fourth sidewall 129 may be a flat surface or a curved surface or may be composed of one section or more sections of sidewalls. The fourth sidewall 129 is designed in the same or similar manner as the first sidewall 111 in the display region 101. The specific design manner may be selected according to practical design requirements, and details are not described herein.

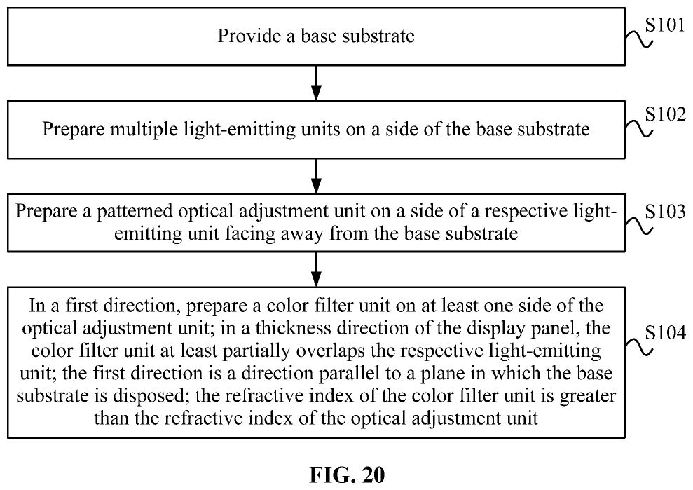

FIG. 20 shows a flowchart of a preparing method for a display panel according to an embodiment of the present invention. As shown in FIG. 20, the method includes the steps described below.

In S101, a base substrate is provided.

In S102, multiple light-emitting units are prepared on a side of the base substrate.

In S103, a patterned optical adjustment unit is prepared on a side of a light-emitting unit facing away from the base substrate.

In S104, in a first direction, a color filter unit is prepared on at least one side of the optical adjustment unit; in a thickness direction of the display panel, the color filter unit at least partially overlaps the light-emitting unit; the first direction is a direction parallel to a flat surface in which the base substrate is disposed; the refractive index of the color filter unit is greater than the refractive index of the optical adjustment unit.

The patterned optical adjustment units formed through a masking technique form a cofferdam structure, facilitating the preparation of the color filter unit between optical adjustment units. The color filter unit may be prepared by a photolithography technique or an inkjet technique to ensure the preparation effect of the structure, thereby ensuring the display effect of the display panel. Meanwhile, the optical adjustment unit is prepared first, and the optical adjustment structure is easily patterned and arranged. The preparation technique is simple, facilitating the formation of inclined sidewalls and the subsequent formation of the color filter unit. Thus, the stability of the overall structure of the display panel is ensured.

In this embodiment of the present invention, a patterned optical adjustment unit is predated on a side of the light-emitting unit, facilitating the preparation of a color filter unit on at least one side of the optical adjustment unit, and ensuring that partial contact exists between the color filter unit and the optical adjustment unit. The refractive index of the color filter unit is greater than the refractive index of the optical adjustment unit so that it is ensured that the light path of the large-angle light emitted by the color filter unit can be changed at the contact point, and the light is emitted in the direction of the front viewing angle. Thus, the light extraction efficiency of the display panel is improved.

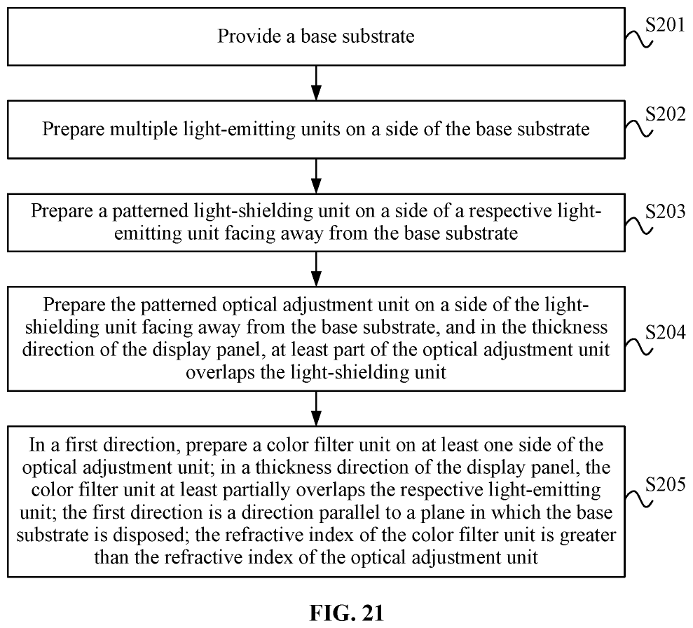

FIG. 21 shows another flowchart of a preparing method for a display panel according to an embodiment of the present invention. As shown in FIG. 21, the method includes the steps described below.

In S201, a base substrate is provided.

In S202, multiple light-emitting units are prepared on a side of the base substrate.

In S203, a patterned light-shielding unit is prepared on a side of a light-emitting unit facing away from the base substrate.

In S204, the patterned optical adjustment unit is prepared on a side of the light-shielding unit facing away from the base substrate, and in the thickness direction of the display panel, the optical adjustment unit at least partially overlaps the light-shielding unit.

A light-shielding layer is generally prepared on a side of the light-emitting unit facing away from the substrate. The light-shielding layer is patterned to form a patterned light-shielding unit to avoid optical crosstalk between subsequent light emitted through adjacent color filter units. Meanwhile, the light-shielding unit is configured to define the formation position of the subsequent optical adjustment unit, reducing the difficulty of the preparation technique, and facilitating the preparation of the optical adjustment unit. Then in the thickness direction of the display panel, the optical adjustment unit is prepared on a side of the light-shielding unit facing away from the base substrate, and the projections of the optical adjustment unit and the light-shielding unit overlap. The optical adjustment unit and the light-shielding unit form a cofferdam structure to facilitate the subsequent preparation of the color filter unit. Moreover, the material of the optical adjustment unit is reasonably selected to ensure that the optical adjustment unit can emit light to ensure transmittance.

In S205, in a first direction, a color filter unit is prepared on at least one side of the optical adjustment unit; in a thickness direction of the display panel, the color filter unit at least partially overlaps the light-emitting unit; the first direction is a direction parallel to a flat surface in which the base substrate is disposed; the refractive index of the color filter unit is greater than the refractive index of the optical adjustment unit.

In this embodiment of the present invention, a patterned light-shielding unit is prepared on a side of the light-emitting unit facing away from the base substrate. The light-shielding unit prevents optical crosstalk between adjacent color filter units and avoids the influence on the display effect. Meanwhile, in the thickness direction of the display panel, the light-shielding unit at least partially overlaps the optical adjustment unit to facilitate subsequent preparation of the color filter unit, thereby improving the light extraction efficiency of the display panel and ensuring the display effect of the display panel.

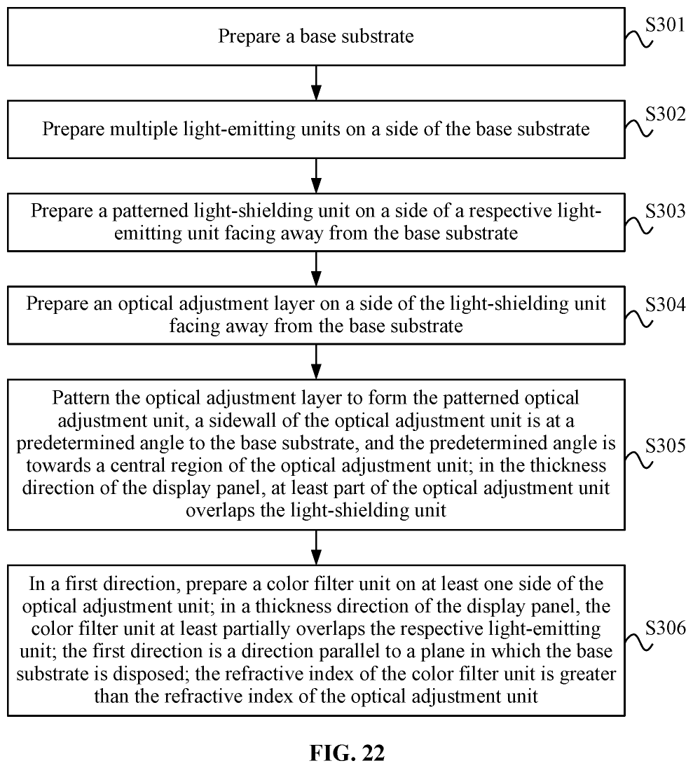

FIG. 22 shows another flowchart of a preparing method for a display panel according to an embodiment of the present invention. As shown in FIG. 22, the method includes the steps described below.

In S301, a base substrate is provided.

In S302, multiple light-emitting units are prepared on a side of the base substrate.

In S303, a patterned light-shielding unit is prepared on a side of a light-emitting unit facing away from the base substrate.

In S304, an optical adjustment layer is prepared on a side of the light-shielding unit facing away from the base substrate.

In S305, the optical adjustment layer is patterned to form the patterned optical adjustment unit, a sidewall of the optical adjustment unit is at a predetermined angle to the base substrate, and the predetermined angle is towards a central region of the optical adjustment unit; in the thickness direction of the display panel, the optical adjustment unit at least partially overlaps the light-shielding unit.

The optical adjustment layer is prepared on a side of the light-shielding unit facing away from the base substrate. The optical adjustment layer is patterned to form a patterned optical adjustment unit. Meanwhile, in the etching formation process, the sidewall of the optical adjustment unit is made to form a predetermined angle so that the predetermined angle faces the center of the optical adjustment unit, and the predetermined angle is between 30° to 80°. The preparation of the predetermined angle may be obtained by the adjustment of the etching depth and the etching speed. Thus, the difficulty of the preparation technique is reduced, and the technique steps are simplified to ensure subsequent matching of the color filter unit, ensure the adjustment effect of the light, and improve the light extraction efficiency at the front viewing angle.

In S306, in a first direction, a color filter unit is prepared on at least one side of the optical adjustment unit; in a thickness direction of the display panel, the color filter unit at least partially overlaps the light-emitting unit; the first direction is a direction parallel to a flat surface in which the base substrate is disposed; the refractive index of the color filter unit is greater than the refractive index of the optical adjustment unit.

In this embodiment of the present invention, a patterned optical adjustment unit is prepared on a side of the light-shielding unit facing away from the base substrate, and a sidewall of the optical adjustment unit is at a predetermined angle to the base substrate, thereby matching the color filter unit; at least partial contact exists between the color filter unit and the optical adjustment unit, and the refractive index of the color filter unit is greater than the refractive index of the optical adjustment unit so that it is ensured that the light path of the large-angle light emitted by the color filter unit can be changed at the contact point. Thus, the light extraction efficiency of the display panel in the direction of the front viewing angle is improved.

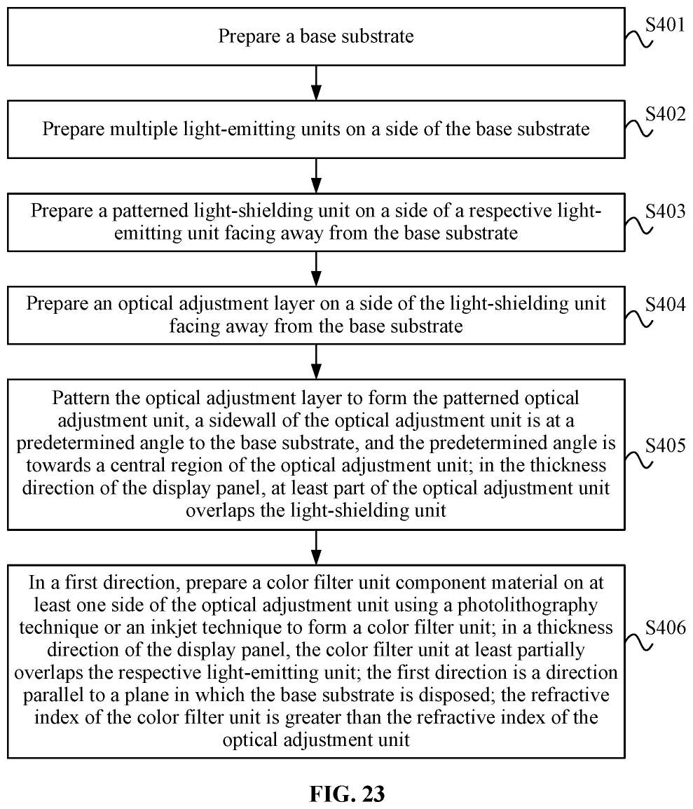

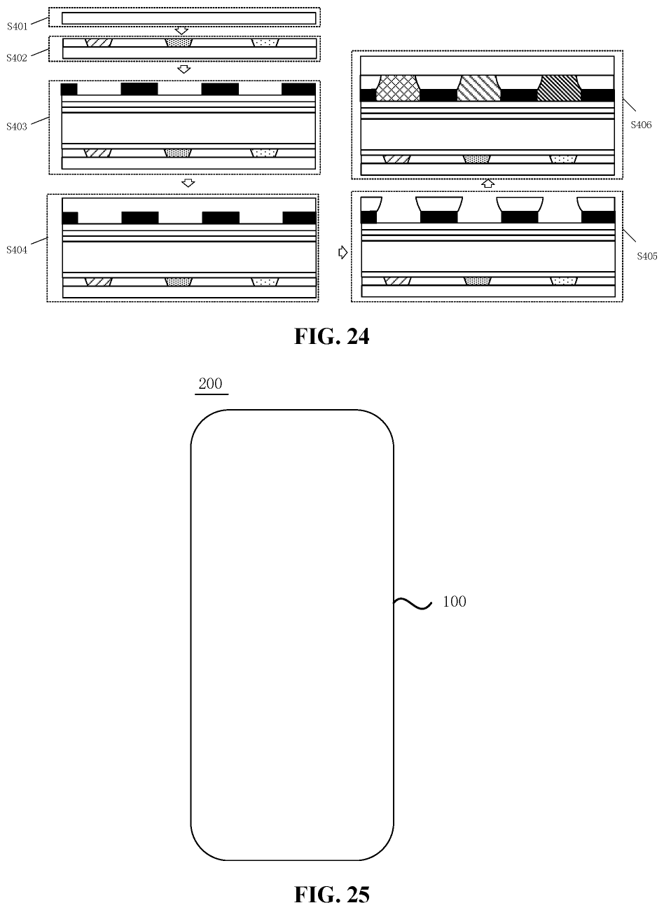

FIG. 23 shows another flowchart of a preparing method for a display panel according to an embodiment of the present invention. FIG. 24 shows another flowchart of a preparing method for a display panel according to an embodiment of the present invention. As shown in FIGS. 23 and 24, the method includes the steps described below.

In S401, a base substrate is provided.

In S402, multiple light-emitting units are prepared on a side of the base substrate.

In S403, a patterned light-shielding unit is prepared on a side of a light-emitting unit facing away from the base substrate.

In S404, an optical adjustment layer is prepared on a side of the light-shielding unit facing away from the base substrate.

In S405, the optical adjustment layer is patterned to form the patterned optical adjustment unit, a sidewall of the optical adjustment unit is at a predetermined angle to the base substrate, and the predetermined angle is towards a central region of the optical adjustment unit; in the thickness direction of the display panel, the optical adjustment unit at least partially overlaps the light-shielding unit.

In S406, in a first direction, a color filter unit component material is prepared on at least one side of the optical adjustment unit using a photolithography technique or an inkjet technique to form a color filter unit; in a thickness direction of the display panel, the color filter unit at least partially overlaps the light-emitting unit; the first direction is a direction parallel to a flat surface in which the base substrate is disposed; the refractive index of the color filter unit is greater than the refractive index of the optical adjustment unit.

A color filter unit component material is prepared on at least one side of the optical adjustment unit using a photolithography technique or an inkjet technique to form a color filter unit to ensure the display effect of the display panel.

In this embodiment of the present invention, a color filter unit is prepared through a photolithography technique or an inkjet technique to ensure the color filter effect of the color filter unit on the light emitted from the light-emitting unit. Meanwhile, the color filter unit is in contact with the optical adjustment unit, and the refractive index of the color filter unit is greater than the refractive index of the optical adjustment unit so that it is ensured that the light path of the large-angle light emitted by the color filter unit can be changed at the contact point. Thus, the light extraction efficiency of the display panel in the direction of the front viewing angle is improved, and the display effect of the display panel is ensured.

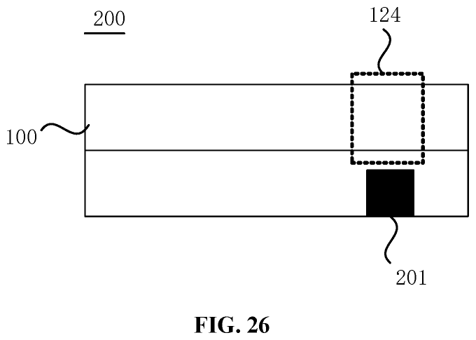

FIG. 25 shows a diagram illustrating a structure of a display device according to an embodiment of the present invention. FIG. 26 shows another diagram illustrating a structure of a display device according to an embodiment of the present invention. As shown in FIGS. 25 and 26, a display device 200 includes the display panel 100 provided in the embodiments.

The display device 200 also includes a sensor 201. The sensor 201 at least partially overlaps the optical device region 124. The sensor may include any photosensitive element such as a camera or an infrared sensor. The sensor 201 is configured correspondingly to the optical device region so that the light transmission of the optical device region 124 is ensured. Moreover, the sensor 201 can receive light normally and work normally, thereby achieving the imaging effect of the display device 200.

It is to be noted that the display device provided in this embodiment has the same or corresponding beneficial effects of the display panel of the embodiments, which is not repeated herein. The display device 200 provided by embodiments of the present invention may be the phone shown in FIG. 25 or may be any electronic product having a display function, including, but not limited to the following categories: a television, a laptop, a desktop display, a tablet computer, a digital camera, a smart bracelet, smart glasses, a vehicle-mounted display, a medical device, an industrial control device, a touch interactive terminal, and no special limitations are imposed thereto in the embodiment of the present invention.

The embodiments do not limit the scope of the present invention. It is to be understood by those skilled in the art that various modifications, combinations, sub-combinations, and substitutions may be performed according to design requirements and other factors. Any modifications, equivalent substitutions, improvements, and the like made within the spirit and principle of the present invention are within the scope of the present invention.

What is claimed is:

1. A display panel, comprising a display region,
wherein the display panel further comprises:
a base substrate;
a plurality of light-emitting units disposed on a side of the base substrate, wherein the plurality of light-emitting units are disposed in the display region;
a color filter layer disposed on a side of the plurality of light-emitting units facing away from the base substrate, wherein the color filter layer comprises a plurality of color filter units, and in a thickness direction of the display panel, a color filter unit of the plurality of color filter units at least partially overlaps a light-emitting unit of the plurality of light-emitting units; and
an optical adjustment layer disposed on a side of the base substrate, wherein the optical adjustment layer comprises a plurality of optical adjustment units, and in a first direction, at least one of the plurality of optical adjustment units is disposed between adjacent color filter units of the plurality of color filter units, and the first direction is a direction parallel to a flat surface in which the base substrate is disposed; and
wherein a refractive index of the color filter unit is greater than a refractive index of an optical adjustment unit of the plurality of optical adjustment units.

2. The display panel of claim 1, wherein the color filter unit comprises at least a first sidewall at least partially in contact with the optical adjustment unit, and
an angle between a tangent to at least one point on the first sidewall and the base substrate and towards a central region of the optical adjustment unit is 0, wherein 100°≤0≤160°.

3. The display panel of claim 2, wherein the first sidewall comprises at least a first sub-sidewall and a second sub-sidewall, the first sub-sidewall is disposed between the second sub-sidewall and the base substrate, and in the thickness direction of the display panel, an angle between a tangent to at least one point of the first sub-sidewall and the base substrate and towards the central region of the optical adjustment unit is different from an angle between a tangent to at least one point of the second sub-sidewall and the base substrate and towards the central region of the optical adjustment unit.

4. The display panel of claim 3, wherein in the thickness direction of the display panel, the angle between the tangent to the at least one point of the first sub-sidewall and the base substrate and towards the central region of the optical adjustment unit is θ1, and the angle between the tangent to the at least one point of the second sub-sidewall and the base substrate and towards the central region of the optical adjustment unit is θ2, wherein θ1>θ2.

5. The display panel of claim 1, wherein at least one of the plurality of color filter units is provided with scattering particles, and a refractive index of the scattering particles is greater than the refractive index of a color filter unit; and wherein the plurality of color filter units comprises at least a first color filter unit and a second color filter unit, the first color filter unit and the second color filter unit have different colors, and a total volume of scattering particles in the first color filter unit is greater than or equal to a total volume of scattering particles in the second color filter unit.

6. The display panel of claim 5, wherein the scattering particles disposed in the first color filter unit includes a first scattering particle and the scattering particles disposed in the second color filter unit includes a second scattering particle, and a particle size of the first scattering particle is greater than or equal to a particle size of the second scattering particle; or,
wherein concentration of the scattering particles in the first color filter unit is greater than or equal to concentration of the scattering particles in the second color filter unit.

7. The display panel of claim 1, wherein the plurality of color filter units comprises at least a first color filter unit and a second color filter unit, the first color filter unit and the second color filter unit have different colors, and in the thickness direction of the display panel, thickness of the second color filter unit is greater than thickness of the first color filter unit.

8. The display panel of claim 1, further comprising a light-shielding unit disposed on at least one side of the color filter unit in the first direction; wherein the light-shielding unit is disposed on a side of the optical adjustment unit facing to the base substrate;
wherein the color filter unit further comprises a second sidewall interconnected to the first sidewall, the second sidewall is at least partially in contact with the light-shielding unit, and the first sidewall is not in contact with the light-shielding unit; and
wherein in the thickness direction of the display panel, the optical adjustment unit at least partially overlaps the light-shielding unit.

9. The display panel of claim 8, wherein in the first direction, an extending width of the optical adjustment unit is greater than or equal to an extending width of the light-shielding unit; and
wherein in the thickness direction of the display panel, a sum of a height of the light-shielding unit and a height of the optical adjustment unit is greater than a height of the color filter unit.

10. The display panel of claim 9, wherein the optical adjustment unit comprises a first surface facing to the side of the base substrate and a second surface facing away from the side of the base substrate, the light-shielding unit comprises a third surface facing away from the side of the base substrate, the first surface is in contact with the third surface, and in the first direction, an extending width of the first surface is less than an extending width of the second surface, and an extending width of the third surface is equal to the extending width of the first surface.

11. The display panel of claim 8, further comprising:
a low refractive index layer disposed on a side of the color filter unit facing away from the base substrate,
wherein in the thickness direction of the display panel, the low refractive index layer at least partially overlaps the color filter unit and a light-shielding unit separately, and a refractive index of the low refractive index layer is less than the refractive index of the color filter unit; and,
wherein the refractive index of the low refractive index layer is less than or equal to the refractive index of the optical adjustment unit.

12. The display panel of claim 11, wherein part of the low refractive index layer is also served as the optical adjustment unit.

13. The display panel of claim 12, wherein the low refractive index layer comprises a first low refractive index section and a second low refractive index section connected to each other; in the thickness direction of the display panel, the first low refractive index section at least partially overlaps the color filter unit, and the second low refractive index section at least partially overlaps the light-shielding unit; and the second low refractive index section comprises a low refractive index sub-section, the low refractive index sub-section is in contact with the light-shielding unit, and the low refractive index sub-section is also served as the optical adjustment unit.

14. The display panel of claim 1, comprising a pixel definition layer disposed on a side of the base substrate, wherein the pixel definition layer is provided with pixel definition structures and a first opening disposed between adjacent pixel definition structures of the pixel definition structures, and in the thickness direction of the display panel, the first opening at least partially overlaps a light-emitting unit and a color filter unit separately, and a pixel definition structure of the pixel definition structures at least partially overlaps an optical adjustment unit; and
wherein in the first direction, an extending width of the pixel definition structure is greater than an extending width of the optical adjustment unit.

15. The display panel of claim 1, further comprising an optical device region, wherein the optical device region comprises:
a plurality of color filter sub-units disposed a side of the base substrate; and
the optical adjustment layer comprises a plurality of optical adjustment sub-units, and in the first direction, at least one optical adjustment sub-unit of the plurality of optical adjustment sub-units is disposed between adjacent color filter sub-units of the plurality of color filter sub-units, and a refractive index of a color filter sub-unit of the plurality of color filter sub-units is greater than a refractive index of an optical adjustment sub-unit of the plurality of optical adjustment sub-units.

16. The display panel of claim 15, wherein the optical device region comprises:
a light-shielding sub-unit disposed on a side of the optical adjustment sub-unit facing to the base substrate and between the adjacent color filter sub-units, wherein the light-shielding sub-unit comprises a second opening; and
an optical adjustment sub-unit, among the at least one optical adjustment sub-unit disposed between the adjacent color filter sub-units, at least partially overlaps both the light-shielding sub-unit and the opening in the thickness direction of the display panel.

17. The display panel of claim 16, wherein the optical adjustment sub-unit comprises a third sidewall and a fourth sidewall connected to each other, the third sidewall is at least partially in contact with the light-shielding sub-unit, the fourth sidewall is not in contact with the light-shielding sub-unit, and an angle between a tangent to at least one point of the fourth sidewall and the base substrate and towards a central region of the optical adjustment sub-unit is β, wherein 100°≤β≤160°.

18. A preparing method for a display panel, comprising:
providing a base substrate;
preparing a plurality of light-emitting units on a side of the base substrate;
preparing a patterned optical adjustment unit on a side of a light-emitting unit of the plurality of light-emitting units facing away from the base substrate; and
in a first direction, preparing a color filter unit on at least one side of the optical adjustment unit, wherein in a thickness direction of the display panel, the color filter unit at least partially overlaps the light-emitting unit; the first direction is a direction parallel to a flat surface in which the base substrate is disposed; and a refractive index of the color filter unit is greater than a refractive index of the optical adjustment unit.

19. The preparing method for the display panel of claim 18, wherein preparing the patterned optical adjustment unit on the side of the light-emitting unit facing away from the base substrate comprises:
preparing a patterned light-shielding unit on the side of the light-emitting unit facing away from the base substrate; and
preparing the patterned optical adjustment unit on a side of the light-shielding unit facing away from the base substrate, wherein in the thickness of the display panel, the optical adjustment unit at least partially overlaps the light-shielding unit; or,
wherein preparing the patterned optical adjustment unit on the side of the light-shielding unit facing away from the base substrate comprises:
preparing an optical adjustment layer on the side of the light-shielding unit facing away from the base substrate; and
patterning the optical adjustment layer to form the patterned optical adjustment unit, wherein a sidewall of the optical adjustment unit is at a predetermined angle to the base substrate, and the predetermined angle is towards a central region of the optical adjustment unit; or,
wherein preparing the color filter unit on the at least one side of the optical adjustment unit comprises:
preparing a color filter unit component material on the at least one side of the optical adjustment unit by using a photolithography technique or inkjet technique to form the color filter unit.

20. A display device, comprising a display panel, wherein the display panel comprises a display region,
wherein the display panel further comprises:
a base substrate;
a plurality of light-emitting units disposed on a side of the base substrate, wherein the plurality of light-emitting units are disposed in the display region;
a color filter layer disposed on a side of the plurality of light-emitting units facing away from the base substrate, wherein the color filter layer comprises a plurality of color filter units, and in a thickness direction of the display panel, a color filter unit of the plurality of color filter units at least partially overlaps a light-emitting unit of the plurality of light-emitting units; and
an optical adjustment layer disposed on a side of the base substrate, wherein the optical adjustment layer comprises a plurality of optical adjustment units, and in a first direction, at least one of the plurality of optical adjustment units is disposed between adjacent color filter units of the plurality of color filter units, and the first direction is a direction parallel to a flat surface in which the base substrate is disposed; and
wherein a refractive index of the color filter unit is greater than a refractive index of an optical adjustment unit of the plurality of optical adjustment units.
